(19) United States
(12) Patent Application Publication
(10) Pub. No.: US 2025/0379597 A1
(43) Pub. Date: Dec. 11, 2025

(54) PRELIMINARY SYNDROME CALCULATION

(71) Applicant: Micron Technology, Inc., Boise, ID (US)

(72) Inventors: Leon Zlotnik, Camion, CA (US); Eyal En Gad, Highland, CA (US)

(21) Appl. No.: 19/231,227

(22) Filed: Jun. 6, 2025

Related U.S. Application Data
(60) Provisional application No. 63/658,544, filed on Jun. 11, 2024.

(51) Int. Cl. H03M 13/15

(52) U.S. Cl. CPC H03M 13/159

(57) ABSTRACT

One or more syndromes can be preliminarily calculated utilizing at least a portion of a codeword and a portion of parity-check matrix can be calculated. The preliminarily calculated syndromes can be utilized to determine where to route the codeword among multiple decoders tailored to various and/or different goals, such as efficiency characteristics, reliability characteristics, etc. of decoding schemes.

### PRIORITY INFORMATION

This application claims the benefit of U.S. Provisional Application No. 63/658,544, filed on Jun. 11, 2024, the contents of which are incorporated herein by reference.

### TECHNICAL FIELD

Embodiments of the disclosure relate generally to electronic systems and, in particular, to electronic systems that perform preliminary syndrome calculations.

### BACKGROUND

Various types of electronic devices such as logic circuits may store and process data. A logic circuit is an electronic circuit that processes digital signals or binary information, which can take on two possible values (usually represented as 0 and 1). The logic circuit can use logic gates to manipulate and transform the signals or binary information. Digital logic circuits can be used in a wide range of electronic devices including, for example, computers, calculators, digital clocks, and many other electronic devices that employ digital processing. Digital logic circuits can be designed to perform specific logical operations on digital inputs to generate digital outputs, and, in some instances, can be combined to form more complex circuits to perform more complex operations.

### BRIEF DESCRIPTION OF THE DRAWINGS

The present disclosure will be understood more fully from the detailed description given below and from the accompanying drawings of various embodiments of the disclosure.

FIG. 1 illustrates an example electronic system that includes a host, a controller, and a device for preliminary syndrome calculation in accordance with some embodiments of the present disclosure.

FIG. 2 is a block diagram that illustrates an example decoding process that utilizes preliminary syndrome calculation circuitry in accordance with some embodiments of the present disclosure.

FIG. 3 illustrates an example sparse parity-check matrix in accordance with some embodiments of the present disclosure.

FIG. 4 is a flow diagram corresponding to a method for preliminary syndrome calculation in accordance with some embodiments of the present disclosure.

FIG. 5 is a block diagram of an example computer system in which embodiments of the present disclosure may operate.

### DETAILED DESCRIPTION

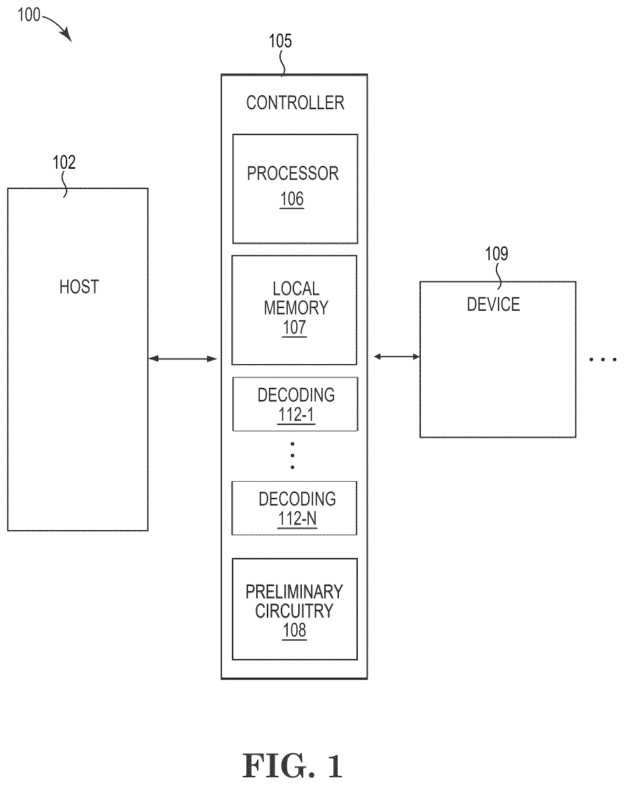

Aspects of the present disclosure are directed to a syndrome decoding system and, in particular, to electronic systems that perform preliminary syndrome calculations. Example electronic systems, or portions thereof, in which embodiments of the present disclosure can operate include, but are not limited to a computing system, a system-on-chip (SoC), a networking system, a communication system, a memory system (e.g., a storage system, a memory module, etc.), an artificial intelligence (AI) system, and a digital entertainment system, among various other types of systems or combinations thereof. Examples of electronic systems are described below in conjunction with FIG. 1.

Data can be written to and stored by one or more digital logic circuits and/or memory systems. The data (e.g., one or more codewords that can correspond to, for example, user data) can be encoded prior to being transferred to the memory device(s) and/or prior to being written to (e.g., stored) by the memory device(s). Upon retrieval of the data, the data is generally decoded. There are many techniques for decoding of codewords, some non-limiting examples of which include maximum likelihood decoding, minimum distance decoding (e.g., decoding techniques that seek to minimize a Hamming distance associated with a codeword), list decoding, linear decoding, bit-flip decoding, and/or information set decoding, among others.

As will be appreciated such decoding techniques can be combined with error correction techniques that can be employed to correct and/or detect bit errors in data (e.g., codewords) based on determining that bits associated with the data have incorrect states (e.g., a “1” where a “0” should be and vice versa). Some of the more common error correction techniques employed include Hamming codes, Reed-Solomon (RS) codes, Bose-Chaudhuri-Hochquenghem (BCH) codes, circular redundancy check (CRC) codes, Golay codes, Reed-Muller codes, Goppa codes, neighbor-cell assisted error correction codes, low-density parity check (LDPC) error correction codes, Denniston codes, and syndrome decoding, among others. While each of these error correction techniques include their own benefits, they also can have various drawbacks. For example, more accurate error correction techniques tend to consume more power and/or time, while less accurate error correction techniques may be performed faster and may consume less power. In the interest of clarity, the present disclosure will be described in terms of linear codes, such as LDPC codes and/or syndrome decoding, which may be generally referred to herein as “error correction techniques” or “decoding techniques,” given the context of the disclosure; however, it will be appreciated that the techniques described herein apply to other decoding techniques as well.

Some approaches may utilize multiple decoders that are tailored to achieve different goals. For example, some current approaches may firstly utilize a first decoder tailored to a high efficiency type of LDPC and/or syndrome decoding and may subsequently transition to a second decoder tailored to a high reliability type of LDPC and/or syndrome decoding when needed. However, this decoding scheme utilizing different decoding techniques may often be more inefficient than utilizing the second decoder alone, particularly when a codeword has errors that the first decoder is not capable of correcting, which inevitably leads to the situation in which the second decoder is required to operate subsequently. Therefore, the operation of the first decoder, in this situation, inevitably introduces unnecessary and/or avoidable latencies associated with decoding the codeword.

In order to address these and other deficiencies of current approaches, embodiments of the present disclosure provide a preliminary syndrome calculation, in which a syndrome calculation is preliminarily performed in order to determine whether to route the codeword to at least one of different decoders (that are tailored to different goals) and, if so, to further determine at least one of the decoders to which the codeword should be routed (e.g., transferred). The circuitry performing a preliminary syndrome calculation (alternatively referred to as “preliminary syndrome calculation circuitry”) operates in a much-simplified manner compared to syndrome calculations and/or decoding processes performed at the various decoders (that perform “full” syndrome calculations) to which the codeword is to be routed. Further, as described further herein, the preliminary syndrome calculation can be performed utilizing merely a particular portion of the codeword and/or a particular portion the parity-check matrix that demonstrates a strong correlation with the overall bit error rate (BER) of the entire codeword (which would generally be indicated by the full syndrome calculation). This allows the preliminary syndrome calculation circuitry to consume less power and/or take less time (than the other decoders to which the codeword is to be routed), yet aims to mitigate the possibility of inaccurately estimating the codeword's BER. Such syndrome decoding schemes that utilize the preliminary syndrome calculation can avoid the situation in which a decoder (e.g., “the first decoder” as mentioned above) that is tailored to an efficiency type unnecessarily attempts to correct errors that are not correctable at the first decoder. Rather, the preliminary syndrome calculation circuitry can selectively route such codewords directly to the second decoder that is tailored to a reliability type (thereby, being capable of successfully decoding the codeword), which can potentially avoid the latencies associated with the unnecessary attempts by the first decoder, for example.

FIG. 1 illustrates an example electronic system 100 that includes a host 102, a controller 105, and a device 109 for preliminary syndrome calculation in accordance with various embodiments of the present disclosure.

The electronic system 100 can be, or can be part of, for example, a desktop computer, laptop computer, televisions, home theater system, gaming console, digital camera, network router and/or switch, printer, scanner, medical device, GPS navigation device, home device (e.g., thermostat, doorbell camera, security camera, smart lock, etc.), wearable device, industrial control system (e.g., automated industrial and/or control device) mobile computing device, a vehicle (e.g., airplane, drone, train, automobile, or other conveyance), Internet of Things (IoT) enabled device, embedded computer (e.g., one included in a vehicle, industrial equipment, or a networked commercial device), system-on-chip (SoC), chipset (e.g., a collection of integrated circuits), tile, Field-Programmable Gate Array (FPGA) structure (e.g., segmented FPGA structure), or other such device.

The electronic system 100 can be, or can include, a computing fabric. As used herein, the term “computing fabric” generally refers to a conveying, multiplexing, network, computing, or communication topology in which components pass data to each other through interconnecting switches, hubs, routers, multiplexers, buses, transmission lines and rings, cables, optical couplers and fibers, electromagnetic devices, or various other means. For example, a “computing fabric” can include various components (e.g., interconnects, crossbars, networks on chip, token rings, etc.) within a computing, memory, data storage and/or processing, network and/or telecommunication, artificial intelligence, control and/or telemetry, digital entertainment and/or other system, that facilitates in-chip and/or inter-chip communication.

The electronic system 100 includes a host 102. The host 102 can include a processor chipset and a software stack executed by the processor chipset. For example, the host 102 can be, or can include, a central processing unit (CPU) or a CPU complex that can be configured to execute an operating system.

The host 102 can be coupled to the controller 105 via a physical and/or logical host interface that operates based on various communication protocols and to provide control, address, data, and other signals to the controller 105 (e.g., to further cause the controller 105 to control the device 109). Examples of the interface between the host 102 and the controller 105 can include, but not limited to, a bus interface (e.g., a serial advanced technology attachment (SATA) interface, a Serial Attached SCSI (SAS) interface, a Serial Attached SCSI (SAS) interface, a Small Computer System Interface (SCSI), a peripheral component interconnect express (PCIe) interface, ISA, etc.), a memory interface (e.g., a double data rate (DDR) interface, a dual in-line memory module (DIMM) interface, an Open NAND Flash Interface (ONFI) interface, an NVM Express (NVMe) interface), a Fibre Channel, an UART interface, an I2C interface, a Serial Peripheral Interface (SPI), an Universal Serial Bus (USB) interface, an ethernet interface, a general-purpose input/output (GIPO) interface, a custom interface, etc.

The controller 105 is communicatively coupled to one or more electronic devices 109 such that signaling can be exchanged therebetween. Non-limiting examples of the devices 109 can include microcontrollers, microprocessors, digital logic circuits, analog circuits, light emitting diodes (LEDs), displays, sensors, motors, actuators, audio amplifiers, radio frequency (RF) circuits, test and measurement instruments (e.g., oscilloscopes, multimeters, etc.), automotive electronics, medical devices, telecommunication equipment, memory devices (e.g., volatile and/or non-volatile memory devices), graphics processing units, processors/co-processors, logic blocks, intellectual property (IP) cores, etc. As used herein, a “core” or “IP core” generally refers to one or more blocks of data and/or logic that form constituent components of an application-specific integrated circuit or field-programmable gate array. The circuit portion areas can be designed, built, and/or otherwise configured to perform specific tasks and/or functions within the systems described herein.

As shown in FIG. 1, the controller 105 can include a processing device (e.g., processor 106) that can execute instructions stored in a local memory 107 to perform various operations described herein. The controller 105 can include various special purpose circuitry in the form of an ASIC, FPGA, state machine, and/or other logic circuitry that can perform operations described herein. As an example, the controller 105 can be a memory controller.

In various embodiments, one or more constituent components (e.g., host 102, controller 105, device 109, etc.) of system 100 can be part of a SoC. In one example, a device 109 itself can correspond to an SoC, while the host 102 and the controller 105 are considered “external” to the SoC. In another example, the host 102 or the controller 105, or both, can be considered as a part of an SoC along with the device 109 being internal or external to the SoC.

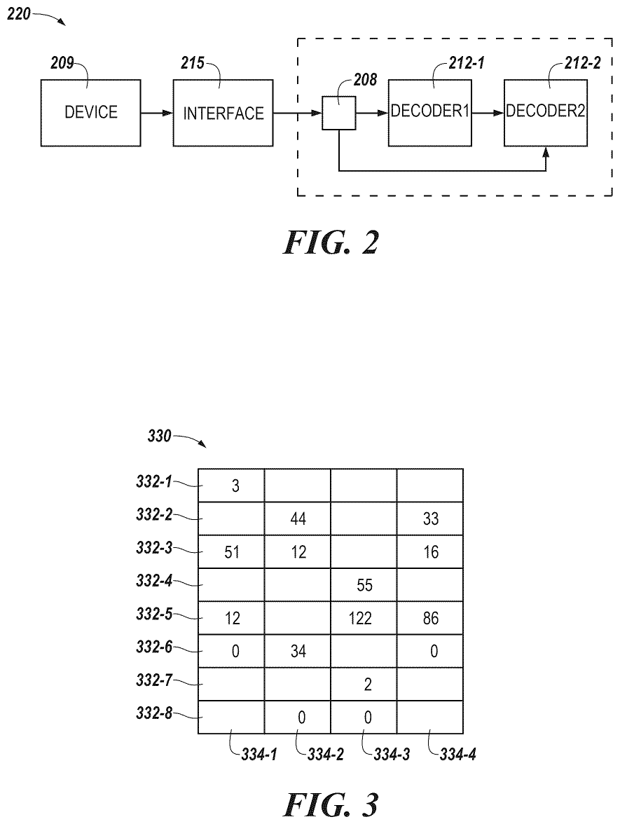

As shown in FIG. 1, the controller 105 can include decoding circuitries 112-1, . . . , 112-N (shown as “decoding” in FIG. 1 and alternatively referred to as “decoders”) as well as preliminary syndrome calculation circuitry 108 (alternatively referred to as “preliminary circuitry” or “simply as “circuitry”). Although not shown in FIG. 1 so as to not obfuscate the drawings, the decoding circuitries 112-1, . . . , 112-N and/or preliminary syndrome calculation circuitry 108 can include various circuitry to facilitate aspects of the disclosure further described herein in FIG. 2 and FIG. 3. In some embodiments, the decoding circuitries 112-1, 112-N and/or the syndrome calculation circuitry 108 can respectively include special purpose circuitry in the form of an ASIC, FPGA, state machine, hardware processing device, and/or other logic circuitry that can allow the decoding circuitries 112-1, . . . , 112-N and/or preliminary syndrome calculation circuitry 108 to orchestrate and/or perform the operations described herein and in accordance with the disclosure.

In some embodiments, the controller 105 includes at least a portion of the syndrome calculation circuitry 108. For example, the controller 105 can include a processor 106 (processing device) configured to execute instructions stored in local memory 107 for performing the operations described herein. In some embodiments, the syndrome calculation circuitry 108 is part of the host 102, an application, or an operating system. The decoding circuitries 112-1, . . . , 112-N and/or preliminary syndrome calculation circuitry 108 can be resident on the controller 105. As used herein, the term “resident on” refers to something that is physically located on a particular component. For example, the decoding circuitries 112-1, . . . , 112-N and/or preliminary syndrome calculation circuitry 108 being “resident on” the controller 105 refers to a condition in which the hardware circuitry that comprises the decoding circuitries 112-1, . . . , 112-N and/or preliminary syndrome calculation circuitry 108 is physically located on the controller 105. The term “resident on” may be used interchangeably with other terms such as “deployed on” or “located on,” herein.

The decoding circuitries 112-1, . . . , 112-N can respectively perform syndrome calculations and/or decoding operations on a quantity of bit strings and/or syndromes to indicate whether the quantity of bit strings and/or syndromes include a quantity of errors and correct the quantity of errors if capable of doing so. The decoding circuitries 112-1, . . . , 112-N can be respectively tailored to achieve different goals. For example, one decoding circuitry 112 can be tailored to an efficiency type (alternatively referred to as “efficiency characteristic”) of decoding techniques, while another decoding circuitry 112 can be tailored to a reliability type (alternatively referred to as “reliability characteristic”) of decoding techniques. The decoding circuitry 112 that is tailored to an efficiency characteristic may utilize less resources than the decoding circuitry 112 tailored to a reliability characteristic, while the decoding circuitry 112 tailored to a reliability characteristic may be capable of correcting errors on the bit strings with a BER exceeding the capability of the decoding circuitry 112 tailored to an efficiency characteristic.

The preliminary syndrome calculation circuitry 108 can route the codeword received from the device (e.g., the device 109) to one of the decoding circuitries 112-1, . . . , 112-N based on the estimated BER of the codeword. The preliminary syndrome calculation circuitry 108 can be simpler than the decoding circuitries 112 in a manner that the syndrome calculation performed at the preliminary syndrome calculation circuitry 108 consumes less power than the power that would have been consumed in association with the syndrome calculations performed at the decoding circuitries 112. Further details of the decoding process utilizing the preliminary syndrome calculation circuitry 108 and decoding circuitries 112-1, . . . , 112-N are illustrated in connection with FIG. 2.

FIG. 2 is a block diagram that illustrates an example decoding process 220 that utilizes preliminary syndrome calculation circuitry 208 in accordance with some embodiments of the present disclosure. The device 209 and the preliminary syndrome calculation circuitry 208 illustrated in FIG. 2 can be analogous to the device 109 and the preliminary syndrome calculation circuitry 108 illustrated in FIG. 1, respectively. Although embodiments are not so limited, the device 209 can be a memory device (e.g., a NAND device), and the interface 215 can be an ONFI interface that operates according to the ONFI protocol. Although embodiments are not so limited, the interface 215 can also include a buffer, in which data (e.g., corresponding to a codeword) can be temporarily stored prior to being transferred further (e.g., to the decoding circuitries 212-1 and/or 212-2).

The decoding circuitries 212-1 and 212-2 (respectively shown as “DECODER1” and “DECODER2” in FIG. 2), which may be collectively referred to as decoding circuitries 212, can be respectively analogous to the decoding circuitries 112-1 and 112-1 shown in FIG. 1. Embodiments are not limited to a particular quantity of decoding circuitries 212 that can be utilized for the decoding process 220. Although embodiments are not so limited, the decoding circuitry 212-1 coupled between the preliminary syndrome calculation circuitry 208 and the decoding circuitry 212-2 can correspond to the decoding circuitry tailored to high efficiency (and may be referred to as a “high efficiency decoder” or “HED”), while the decoding circuitry 212-2 can correspond to the decoding circuitry tailored to a high reliability (simply referred to as “high reliability decoder” or “HRD”). Although embodiments are not so limited, the decoding circuitry 212-1 can be/include a bit-flipping decoder, while the decoding circuitry 212-2 can be/include a MIN-SUM decoder, for example. As used herein, the term “bit flipping decoder” refers to a decoder that utilizes a simple iterative algorithm (e.g., utilized in error-correcting codes like LDPC and binary linear block codes), which iteratively corrects received codewords by flipping individual bits violating parity constraints until convergence or a maximum iteration limit is reached. Further, as used herein, the term “MIN-SUM decoder” refers to a decoder that utilizes iterative message-passing algorithm (e.g., used in error-correcting codes such as LDPC and turbo codes), which aims to minimize the sum of log-likelihood ratios associated with each bit to determine the most likely transmitted codeword in the presence of noise.

Although not illustrated in details in FIG. 2, the decoding circuitry 212 can include various circuitry to perform the operations (e.g., syndrome calculations, decoding operations, etc.), such as arrays of memory cells, various logic gates (AND gates, OR gates, NOT gates, NAND gates, NOR gates, XOR gates, etc.), multiplexer (MUX)/de-MUX gates, shifting circuitry, decision engines, although embodiments are not so limited. The decision engines of the decoding circuitries can flip one or more bits of codewords (alternatively referred to as “bit strings”) and/or syndrome based on a determined probability that such bits are erroneous. As used herein, the term “codeword” generally refers to a data word having a specified size (e.g., 4 KB, etc.) that is encoded such that the codeword can be individually protected by some error encoding and/or decoding scheme. For example, a “codeword” can refer to a set of bits (e.g., a bit string) that can be individually encoded and/or decoded.

The probability that one or more bits are erroneous can be determined using various linear codes, such as syndrome decoding codes, LDPC codes, etc. Embodiments are not limited to cases in which the decoding circuitry 212 corrects the errors based on a determined probability that such bits are erroneous (e.g., through the use of a linear decoding technique), however, and in some embodiments, the decoding circuitry 212 can determine which bits of the bit strings and/or syndromes are erroneous based on mathematical inference algorithms, machine learning algorithms, and/or other suitable techniques for determining which bits of the bit strings and/or syndromes are erroneous.

While error correction techniques described in association with FIGS. 1-5 are exemplified by “syndrome calculation”, it is crucial to note that the error correction technique utilizing syndromes and described herein is merely an example representation of codeword errors. Different error correction algorithms, such as, but not limited to, parity, error signature, CRC sum, and others, may also be utilized for the decoding process 220. Alternatively speaking, a preliminary “error assessment” and/or further error correction and/or decoding operations that may be performed at the decoders 212 are not limited to a syndrome calculation, but may include other various error correction techniques, such as, but not limited to, parity, error signature, CRC sum, and others and without being constrained by specific error correction algorithms.

The decoding circuitries 212 can include shift circuitry that can be further used during the syndrome calculations and/or decoding operations. As used herein, the term “syndrome calculation” refers to one or more operations that calculates (e.g., generates) a syndrome and/or correct one or more bits of the calculated syndrome, while the term “decoding operation” refers to an operation that attempts to correct one or more bit errors based on the calculated syndromes. The syndrome calculated at the decoding circuitries 212 (and/or preliminary syndrome calculation circuitry 208) can reflect a current error state associated with data contained within the bit string (e.g., codeword). For example, the value of the syndromes (e.g., calculated at the preliminary syndrome calculation circuitry 208) being zero implies that the bit string has no errors and thus has been successfully decoded. However, each bit of the syndromes having a particular logical value (e.g., “1”) can make the value of the syndromes non-zero; thereby, indicating that the bit string has errors. As used herein, a quantity of bits having the particular logical value, such as “1”, of the syndrome can be referred to as “syndrome weight” (alternatively referred to as “a quantity of parity violations”), which can correlate to a quantity of errors and/or a bit error rate (BER). Alternatively speaking, the determined syndrome weight can be an estimate of the BER of the bit string.

Alternatively speaking, various operations performed at the decoding circuitries 212 make reference to both bit strings and/or syndromes in order to illustrate various aspects of the present disclosure. In some embodiments, when one or more bits of a bit string are corrected, a corresponding syndrome can be updated to reflect a current error state of the syndrome.

Although embodiments are not so limited, the syndrome calculations and/or decoding operations performed at the decoding circuitries 212 can be iterative. For example, one or more erroneous bit of a bit string identified and/or a “non-zero” syndrome calculated as a result of the first iteration of the syndrome calculation and/or decoding operation may be corrected during a second iteration of the syndrome calculation and/or decoding operation, and one or more remaining erroneous bit of the bit string identified and/or a “non-zero” syndrome calculated as a result of the second iteration of the syndrome calculation may be corrected during a third iteration of the syndrome calculation and/or decoding operation. Decoding of bit strings and/or syndromes at the decoding circuitries 212 can be achieved by shifting the bit strings and/or syndromes using shift circuitry, which can include one or more barrel shifters. The barrel shifters are configured to shift (e.g., cyclically shifting, which is alternatively referred to as “circular shifting”) the bit strings and/or syndromes by a specified number of bits, for example, using pure combinatorial logic. Embodiments are not so limited; however, and it is contemplated within the disclosure that the shift circuitry can be configured to perform shift operations involving the bit strings and/or syndromes utilizing other combinatorial logic techniques (e.g., circular shifting, etc.) and/or sequential logic techniques.

In some embodiments, the bit strings and/or syndromes that are processed (e.g., subjected to the operations described above as part of decoding the bit strings and/or syndromes) are determined by values in columns of a parity-check matrix (e.g., an H matrix, such as an H matrix 330 illustrated in FIG. 3) and the quantity of bits by which the barrel shifters shift the bits of the bit strings and/or syndromes are generally determined based on values indicated by bit patterns aligned in a particular orientation (e.g., the bit patterns respectively corresponding to rows, which can be grouped into “layers”, such as layers 332 illustrated in FIG. 3) of the parity-check matrix. For example, which bit strings and/or syndromes to decode are selected (i.e., blocks of parity checks) based on corresponding values in the columns of the parity-check matrix and an offset by which to cyclically shift the bit strings and/or syndromes by the one or more barrel shifters is selected based on corresponding values in the rows of the parity-check matrix. As used herein, rows and columns of a parity-check matrix can be referred to as bit patterns aligned in respective orientation. For example, a row can be referred to as a bit pattern aligned in a first orientation and a column can be referred to as a bit pattern aligned in a second orientation, or vice versa.

The preliminary syndrome calculation circuitry 208 is located close to the interface 215 in a manner that a codeword transferred via the interface 215 is received to the preliminary syndrome calculation circuitry 208 prior to the decoding circuitries 212. Alternatively, although the preliminary syndrome calculation circuitry 208 is illustrated as being separate from the interface 215, the preliminary syndrome calculation circuitry 208 can be also part of the interface 215 and/or the device 209 in some embodiments. For example, the preliminary syndrome calculation circuitry 208 can be resident on the interface 215. The close coupling or the fact that the preliminary syndrome calculation circuitry 208 is part of the interface 215 allows a preliminary syndrome to be available at an early stage of the codeword processing (e.g., accessing codewords from the device 109 illustrated in FIG. 1 and/or decoding the codewords at the decoding circuitries 212).

The preliminary syndrome calculation circuitry 208 can perform a syndrome calculation (based on the codeword received from the interface 215) and/or decoding operations partially on the bit strings received from the interface 215. Although embodiments are not so limited, the preliminary syndrome calculation can be performed by accessing a codeword store in a buffer of the interface 215.

The syndrome calculation performed at the preliminary syndrome calculation circuitry 208 can be “on the fly” and a simplified version of the syndrome calculation performed at the decoding circuitries 212-1, 212-2. For example, the preliminary syndrome calculation circuitry 208 can perform a syndrome calculation using merely a portion of the parity-check matrix (e.g., the sparse parity-check matrix 330 illustrated in FIG. 3), such as one “layer” (e.g., the layer 332-8 illustrated in FIG. 3) among layers of the parity-check matrix. Accordingly, such syndrome calculation can involve merely a portion of the codeword that corresponds only to the portion of the parity-check matrix. As used herein, a syndrome calculated at the preliminary syndrome calculation circuitry 208 can be referred to as “preliminary syndrome”.

In a number of embodiments, such layer used for the syndrome calculation at the preliminary syndrome calculation circuitry 208 can be a layer that does not require barrel shifters. Alternatively speaking, a shifting indicator (e.g., how many bits of the portion of the codeword and/or syndrome will be shifted for the syndrome calculation) corresponding to such a layer is zero such that the syndrome calculation can be performed without shifting bits of the portion of the codeword and/or syndrome. Further details of layers and the parity-check matrix is described in connection with FIG. 3.

Although embodiments are not so limited, the syndrome calculation performed at the preliminary syndrome calculation circuitry 208 can be iterative. For example, one or more erroneous bit of a “non-zero” syndrome calculated as a result of the first iteration of the syndrome calculation may be corrected during a second iteration of the syndrome calculation, and one or more remaining erroneous bit of a “non-zero” syndrome calculated as a result of the second iteration of the syndrome calculation may be corrected during a third iteration of the syndrome calculation.

The preliminary syndrome calculation circuitry 208 can further determine where to route the codeword based on the determined syndrome weight. For example, if the determined syndrome weight exceeds the threshold (which indicates that the syndrome may not be successfully decoded at the decoding circuitry 212-1), the syndrome can be routed to the decoding circuitry 212-2 directly (e.g., by bypassing the decoding circuitry 212-1). For example, if the determined syndrome weight does not exceed the threshold (which indicates that the syndrome may be successfully decoded at the decoding circuitry 212-1), the calculated syndrome can be routed to the decoding circuitry 212-1. The determination involving the routing can be performed by a decision component of the preliminary syndrome calculation circuitry 208 that can be implemented in forms of hardware, firmware, or any combination thereof.

This routing scheme can potentially avoid the situation where the codeword is unnecessarily routed to the decoding circuitry 212-1 when errors need to be corrected at the decoding circuitry 212-2 anyhow due to the high BER of the codeword exceeding the capability of the decoding circuitry 212-1. Still, the decoding circuitry 212-1 may also be configured to route the calculated syndrome to the decoding circuitry 212-2 in the event that the syndrome received from the preliminary syndrome calculation circuitry 208 was not successfully decoded at the decoding circuitry 212-1. Otherwise (if the syndrome was successfully decoded at the decoding circuitry 212-1), the syndrome may not be routed to the decoding circuitry 212-2.

If the syndrome weight determined by the preliminary syndrome calculation circuitry 208 exceeds another threshold, which is beyond the decoding capability of any one of the decoding circuitries 212 (e.g., even the decoding circuitry 212-2 tailored to a reliability characteristic), the preliminary syndrome calculation circuitry 208 and/or the controller 105 illustrated in FIG. 1 may not initiate the decoding process at the decoding circuitries 212. For example, the codeword that has been stored in the buffer may not be transferred to the decoding circuitries 212. Rather, in some embodiments, the preliminary syndrome calculation circuitry 208 and/or the controller 105 can request the device 209 to re-transfer the codeword, which can be written again to the buffer where the preliminary syndrome calculation can be performed again. Accordingly, in the event that the codeword is to be re-transferred from the device 209 to the interface 215 in the above-mentioned scenario, the latencies associated with decoding the codeword can be substantially reduced compared to those approaches where a “full” syndrome calculation (e.g., at the decoding circuitries, such as bit-flip decoder, MIN-SUM decoder, etc.) was required to have been performed prior to determining that the re-transfer of the codeword is necessary. In some embodiments, in which a syndrome resulted from the syndrome calculation performed at the preliminary syndrome calculation circuitry 208 corresponds to a “full” syndrome (as opposed to “partial” syndrome calculated only a portion of the matrix 330 illustrated in FIG. 3), the corresponding codeword may not be routed to any one of the decoders 212-1 or 212-2 if the full syndrome calculated at the preliminary syndrome calculation circuitry 208 is determined to be a zero syndrome (e.g., syndrome weight is zero). Alternatively speaking, the codeword may instead be read (e.g., to the host 102 illustrated in FIG. 1) without triggering operation of the decoders 212-1 and 212-2 in such events.

FIG. 3 illustrates an example sparse parity-check matrix 330 in accordance with some embodiments of the present disclosure. The sparse parity-check matrix can be referred to as an “H-matrix” in accordance with parlance common in the art and can be used to specify an error correction code, such as a low-density parity check code. Further, although embodiments are not so limited, the parity-check matrix 330 illustrated in FIG. 3 can be of a quasi-cyclic LDPC code. The sparse parity-check matrix 330 can be stored in the preliminary syndrome calculation circuitry 108 and/or the decoding circuitries 112-1, . . . , 112-N. Alternatively the sparse-parity-check matrix 330 can be stored in a memory separate from the preliminary syndrome calculation circuitry 108 and/or the decoding circuitries 112-1, . . . , 112-N.

The sparse parity-check matrix can include layers, such as layer 332-1, . . . , 332-8 illustrated in FIG. 3. The sparse parity-check matrix 330 may not be illustrated in its entirety in FIG. 3. Accordingly, the sparse parity-check matrix 330 can include more or less than 8 layers. Further, each layer 332 can include a number of “entries”, which can be defined by intersections of 332 (332-1, . . . , 332-8) and 334 (334-1, . . . , 334-4). For example, as illustrated in FIG. 3, the layer 332-8 includes 4 entries which are respectively located at intersections of 332-8 and 334-1, 332-8 and 334-2, 332-8 and 334-3, and 332-8 and 334-4. Embodiments are not limited to a particular orientation of a parity-check matrix, in which bit patterns (corresponding to rows and/or columns) can be aligned. For example, while FIG. 3 illustrates layers 332-1, . . . , 332-8 of the parity-check matrix 330 aligned in an orientation corresponding to “row”, the layers 332-1, . . . , 332-8 can also be aligned in a different orientation corresponding to “column”.

Although not illustrated in FIG. 3 in detail, each layer consists of a particular quantity of rows, such as one hundred twenty-eight (128) rows, although embodiments are not limited to this particular enumerated quantity of rows. The quantity of rows corresponding to each layer can be referred to as the circulant size for the sparse-parity-check matrix 330.

As an example, the layer 332-1 of the sparse-parity-check matrix 330 can include a quantity of rows, such as one hundred twenty-eight (128) rows; the layer 332-2 of the sparse-parity-check matrix 330 can include another quantity of rows, such as another hundred twenty-eight (128) rows; the layer 332-3 of the sparse-parity-check matrix 330 can include another quantity of rows, such as another hundred twenty-eight (128) rows; the layer 332-4 of the sparse-parity-check matrix 330 can include another quantity of rows, such as another hundred twenty-eight (128) rows; the layer 332-5 of the sparse-parity-check matrix 330 can include another quantity of rows, such as another hundred twenty-eight (128) rows; the layer 332-6 of the sparse-parity-check matrix 330 can include another quantity of rows, such as another hundred twenty-eight (128) rows; the layer 332-7 of the sparse-parity-check matrix 330 can include another quantity of rows, such as another hundred twenty-eight (128) rows; and the layer 332-8 of the sparse-parity-check matrix 330 can include another quantity of rows, such as another hundred twenty-eight (128) rows.

Each layer can also include a quantity of columns and each column can correspond to a respective bit of the codeword. For example, if the codeword includes 37,000 bits, each layer can include 37,000 columns (with each column having a number of binary values, such as “0” or “1”). Further, each entry of the layer can include a particular quantity of columns, such as 128 columns, although embodiments are not so limited. Therefore, in this particular example, a syndrome calculation for each entry having 128 columns involves performing XOR operations utilizing 128 bits of the codeword.

As shown in FIG. 3, the sparse parity-check matrix 330 includes numerical values. For example, the layer 332-1 includes a numerical value of “3” at an entry located at 334-1; the layer 332-2 includes numerical values of “44” and “33” at entries respectively located at 334-2 and 334-4; the layer 332-3 includes numerical values of “51”, “12”, and “16” at entries respectively located at 334-1, 334-2, and 334-4; the layer 332-4 includes numerical values of “55” at an entry located at 334-3; the layer 332-5 includes numerical values of “12”, “122”, and “86” at entries respectively located at 334-1, 334-3, and 334-4; the layer 332-6 includes numerical values of “0”, “34”, and “0” at entries respectively located at 334-1, 334-2, and 334-4; the layer 332-7 includes numerical values of “2” at an entry located at 334-3; and the layer 332-8 includes numerical values of “0” and “0” at entries respectively located at 334-2 and 334-3.

Each numerical value is indicative of a quantity of bits by which the corresponding syndrome is to be shifted (e.g., using one or more barrel shifters) during syndrome calculations and/or decoding operations performed at the decoding circuitry 212-1 and/or decoding circuitry 212-2. For example, the syndrome calculation and/or decoding operations performed utilizing the layer 332-1 involves shifting the corresponding bit string and/or syndrome by “3”. Further, for example, the syndrome calculations and/or decoding operations performed utilizing the layer 332-5 involves shifting the corresponding bit string and/or syndrome (e.g., corresponding to the entry located at 334-1 of the layer 332-5) by “12”, shifting the corresponding bit string and/or syndrome (e.g., corresponding to the entry located at 334-3 of the layer 332-5) by “122”, and shifting the corresponding bit string and/or syndrome (e.g., corresponding to the entry located at 334-4 of the layer 332-5) by “86”.

Syndrome calculations performed at the preliminary syndrome calculation circuitry 208 can be performed using a portion of the layers, such as the 332-8 (e.g., a last layer) only. Syndrome calculations and/or decoding operations performed utilizing the layer 332-8 do not involve shifting bits of the corresponding bit string and/or syndromes as the numerical values of the layer 332-8 are “0”. While embodiments are not so limited, selecting this layer for the preliminary syndrome calculation (performed at the preliminary syndrome calculation circuitry 208) can eliminate a need to have shifting circuitry (e.g., barrel shifters) at the preliminary syndrome calculation circuitry 208; thereby, reducing the latencies associated with calculating syndromes.

Syndrome calculations can be selectively performed depending on whether a respective entry of each layer 332 includes a numerical value or not. For example, when performing syndrome calculations utilizing the layer 332-2, the syndrome calculations can be selectively performed utilizing portions of the codeword corresponding to one entry having “44” (and located at 334-2 of the layer 332-2) and another entry having “33” (and located at 334-4 of the layer 332-2), while syndrome calculations that would have been performed utilizing portions of the codeword corresponding to entries respectively located at 334-1 and 334-3 may not be performed.

In some embodiments, a syndrome calculation (e.g., preliminary syndrome calculation) utilizing the layer 332-8 can include multiplying a first portion (e.g., a quantity of bits, such as 128 bits, corresponding to an “entry” and alternatively referred to as “relevant part”) of the codeword by columns of the entry located at 334-2 of the layer 332-8 and a second portion (e.g., a quantity of bits, such as 128 bits, corresponding to an “entry”) of the codeword by rows of the entry located at 334-3 of the layer 332-8. Although embodiments are not so limited, the multiplication of the respective portion by the parity-check matrix 330 (e.g., a respective entry of the parity-check matrix 330) can include XORing each bit of the portion (e.g., 128 bits) with each bit of a respective row (e.g., having 128 bits respectively on 128 columns) of the entry. In some embodiments, a quantity of bits of the codeword (e.g., 256 bits, although embodiments are not so limited) corresponding to two entries located at 334-1 and 334-4 of the layer 332-8 may not be utilized in calculating the syndromes. In sum, an equation corresponding to a syndrome calculation can be expressed as follows:

$$s = {\sum }_{i = 0}^{127} {⊕}_{j = 0}^{r - 1} w ( {L}_{j} * 128 + i )$$

where “S” is a syndrome weight, “W” is a word (e.g., codeword), “i” is a row index, which can range from “0” to “127” (e.g., 128 iterations as defined by the circulant size), and “r” is a row weight indicating a number of non-empty entries in the row. Further, “Lj” is the index of the j-th non-empty column in the layer with “j” ranging from “0”. For example, the “Lj” on the layer 332-1 starts from the index “0” (corresponding to a column 334-1), while the “Lj” on the layer 332-2 starts from the index “1” (corresponding to a column 334-2).

In a number of embodiments, a syndrome weight calculated from the layer 332-8 demonstrates a strong correlation with the BER of the codeword. This correlation enables the preliminary syndrome to serve as a primary factor in deciding the routing destination for the codeword (e.g., to the decoding circuitry 212-1 or the decoding circuitry 212-2 illustrated in FIG. 2). This aims to mitigate the possibility of inaccurately estimating the codeword's BER, which could otherwise lead to suboptimal routing decisions, and undesirably and increased decoding latencies at the decoding circuitries 212. While the layer 332-8 can be a “last” layer as shown in FIG. 3 (e.g., located at the bottom of the parity-check matrix 330), the parity-check matrix 330 can be designed in a manner that embodiments are not limited to a geometrical location of this layer (e.g., the layer 332-8) utilized by the preliminary syndrome calculation circuitry 108, 208 within the parity-check matrix 330.

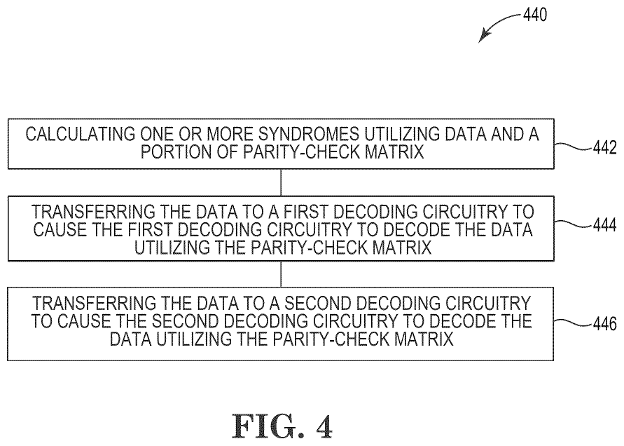

FIG. 4 is a flow diagram corresponding to a method 440 for preliminary syndrome calculation in accordance with some embodiments of the present disclosure. The method 440 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 440 is performed by the syndrome calculation circuitry 108, 208 of FIGS. 1-2 and/or the controller 105 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 442, the method 440 includes calculating one or more syndromes (e.g., at the preliminary circuitry 108, 208 illustrated in FIGS. 1-2 herein) utilizing data (e.g., corresponding to a codeword) and a portion of parity-check matrix (e.g., the parity-check matrix 330 illustrated in FIG. 3 herein). At operation 444, the method 440 further includes transferring the data to a first decoding circuitry (e.g., the decoding circuitry 112, 212-1 illustrated in FIGS. 1-2 herein) to cause the first decoding circuitry to decode the data utilizing the parity-check matrix 330 responsive to determining that a syndrome weight of the one or more syndromes does not exceed the threshold syndrome weight.

At operation 446, the method 440 further includes transferring the data to a second decoding circuitry 112, 212-2 (e.g., the decoding circuitry 112, 212-2 illustrated in FIGS. 1-2 herein) to cause the second decoding circuitry 112, 212-2 to decode the data utilizing the parity-check matrix 330 responsive to determining that a syndrome weight of the one or more syndromes exceeds the threshold syndrome weight. For example, the data can be transferred (alternatively referred to as “routed”) to the second decoding circuitry 112, 212-2 by bypassing the first decoding circuitry 112, 212-1 such that the first decoding circuitry 112, 212-1 does not perform a decoding operation on the data.

In some embodiments, the data corresponding to the codeword can also be selectively transferred to the second decoding circuitry 112, 212-2 from the first decoding circuitry 112, 212-1. For example, the method 440 can include performing, at the first decoding circuitry 112, 212-1, a decoding operation on the data utilizing the parity-check matrix 330. Continuing with this example, the method 440 can further include transferring the data from the first decoding circuitry 112, 212-1 to the second decoding circuitry 112, 212-2 responsive to determining that one or more syndromes generated as a result of performing the decoding operation indicates one or more errors remaining in the data.

In some embodiments, the one or more syndromes can be calculated utilizing at least one layer (e.g., the layer 342-8 illustrated in FIG. 3 herein) of the parity-check matrix 330 that does not involve shifting bits of the data or a corresponding syndrome when decoded at the first decoding circuitry 112, 212-1 or the second decoding circuitry 112, 212-2, or both. Accordingly, in some embodiments, the preliminary circuitry 108, 208 may not include circuitry (e.g., barrel shifters) configured to shift bits of the codeword and/or corresponding syndromes (e.g., the one or more syndromes), while the first and second decoding circuitries 112, 212 may include the circuitry (e.g., barrel shifters).

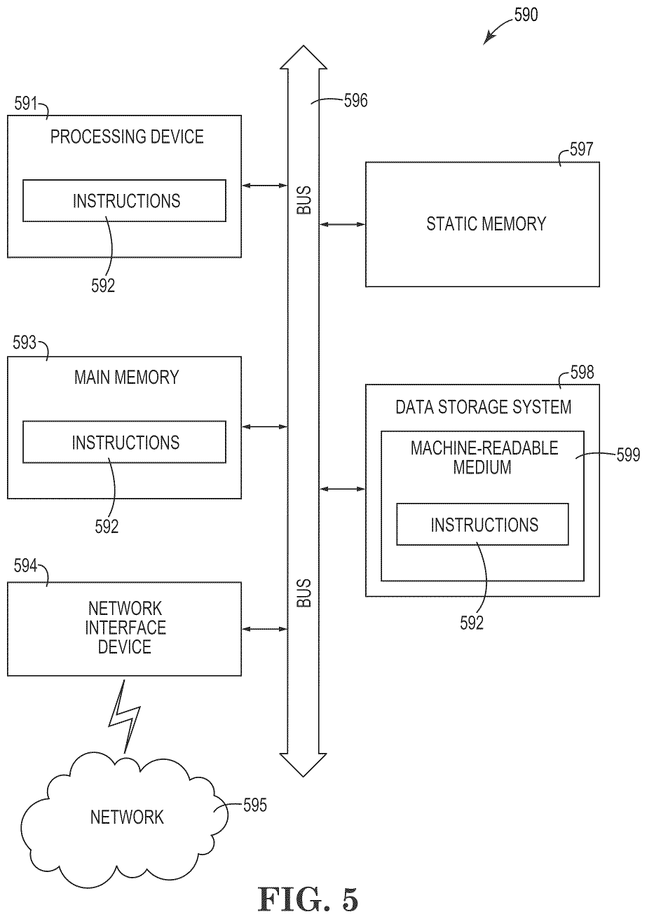

FIG. 5 is a block diagram of an example computer system in which embodiments of the present disclosure may operate. For example, FIG. 5 illustrates an example machine of a computer system 590 within which a set of instructions, for causing the machine to perform any one or more of the methodologies discussed herein, can be executed. In some embodiments, the computer system 590 can correspond to a host system (e.g., the host system 102 of FIG. 1) that includes, is coupled to, or utilizes a controller and/or a device (e.g., the controller 105 and/or the device 109 of FIG. 1) or can be used to perform the operations of a controller (e.g., to execute an operating system to perform operations corresponding to the preliminary syndrome calculation circuitry 108 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 590 includes a processing device 591, a main memory 593 (e.g., read-only memory (ROM), flash memory, dynamic random access memory (DRAM) such as synchronous DRAM (SDRAM) or Rambus DRAM (RDRAM), etc.), a static memory 597 (e.g., flash memory, static random access memory (SRAM), etc.), and a data storage system 598, which communicate with each other via a bus 596.

The processing device 591 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 591 can also be one or more special-purpose processing devices such as an application specific integrated circuit (ASIC), a field programmable gate array (FPGA), a digital signal processor (DSP), network processor, or the like. The processing device 591 is configured to execute instructions 592 for performing the operations and steps discussed herein. The computer system 590 can further include a network interface device 594 to communicate over the network 595.

The data storage system 598 can include a machine-readable storage medium 599 (also known as a computer-readable medium) on which is stored one or more sets of instructions 592 or software embodying any one or more of the methodologies or functions described herein. The instructions 592 can also reside, completely or at least partially, within the main memory 593 and/or within the processing device 591 during execution thereof by the computer system 590, the main memory 593 and the processing device 591 also constituting machine-readable storage media. The machine-readable storage medium 599, data storage system 598, and/or main memory 593 can correspond to the controller 105 of FIG. 1.

In one embodiment, the instructions 592 include instructions to implement functionality corresponding to syndrome calculation circuitry (e.g., the preliminary syndrome calculation circuitry 108 of FIG. 1). While the machine-readable storage medium 599 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method, comprising:
calculating one or more syndromes utilizing data and a portion of parity-check matrix;
responsive to determining that a syndrome weight of the one or more syndromes does not exceed a threshold syndrome weight, transferring the data to a first decoding circuitry to cause the first decoding circuitry to decode the data utilizing the parity-check matrix; and
responsive to determining that a syndrome weight of the one or more syndromes exceeds the threshold syndrome weight, transferring the data to a second decoding circuitry to cause the second decoding circuitry to decode the data utilizing the parity-check matrix.

2. The method of claim 1, wherein transferring the data to the second decoding circuitry to cause the second decoding circuitry to decode the data utilizing the parity-check matrix further comprises bypassing the first decoding circuitry such that the first decoding circuitry does not perform a decoding operation on the data.

3. The method of claim 1, further comprising:
performing, at the first decoding circuitry, a decoding operation on the data utilizing the parity-check matrix; and
responsive to determining that one or more syndromes generated as a result of performing the decoding operation indicates one or more errors remaining in the data, transferring the data from the first decoding circuitry to the second decoding circuitry.

4. The method of claim 1, further comprising calculating the one or more syndromes utilizing data and the portion of parity-check matrix further comprises:
calculating the one or more syndromes utilizing at least one layer of the parity-check matrix that does not involve shifting bits of the data when decoded at the first decoding circuitry or the second decoding circuitry, or both.

5. An apparatus, comprising:
a plurality of decoding circuitries comprising a first decoding circuitry and a second decoding circuitry, wherein:
the first decoding circuitry is configured to perform a decoding operation on data utilizing a parity-check matrix, wherein the data is transferred to the second decoding circuitry in response to the decoding operation performed at the first decoding circuitry being determined to have not corrected one or more errors on the data; and
preliminary circuitry configured to:
calculate a syndrome utilizing data and a portion of the parity-check matrix; and
determine whether to transfer the data to the first decoding circuitry or the second decoding circuitry based on a comparison between a syndrome weight of the calculated syndrome and a threshold syndrome weight.

6. The apparatus of claim 5, wherein the preliminary circuitry is configured to transfer the data directly to the second decoding circuitry to cause the second decoding circuitry to perform a decoding operation on the data utilizing the parity-check matrix in response to determining that the syndrome weight of the calculated syndrome exceeds the threshold syndrome weight.

7. The apparatus of claim 5, wherein the preliminary circuitry is further configured to transfer the data to the first decoding circuitry to cause the first decoding circuitry to perform a decoding operation on the data in response to determining that the syndrome weight of the syndrome does not exceed the threshold syndrome weight.

8. The apparatus of claim 5, wherein the preliminary circuitry is further configured to bypass the first decoding circuitry to transfer the data directly to the second decoding circuitry.

9. The apparatus of claim 5, wherein
the first decoding circuitry is tailored to an efficiency characteristic; and
the second decoding circuitry is tailored to a reliability characteristic.

10. The apparatus of claim 5, wherein the parity-check matrix comprises a plurality of sets of first bit patterns aligned in a first orientation.

11. The apparatus of claim 10, wherein:
each set of first bit patterns of the plurality of sets of first bit patterns of the parity-check matrix is associated with a respective numeric value indicative of a quantity of bits by which the data or a corresponding syndrome is to shift by the first decoding circuitry during the decoding operation performed by the first decoding circuitry.

12. The apparatus of claim 11, wherein the portion of the parity-check matrix corresponds to a set of first bit patterns among the plurality of sets of first bit patterns of the parity-check matrix.

13. The apparatus of claim 12, wherein the respective numeric value associated with the set of first bit patterns corresponding to the portion of the parity-check matrix is zero such that a quantity of bits the data or a corresponding syndrome to shift by the first decoding circuitry is zero.

14. The apparatus of claim 5, wherein the preliminary circuitry does not include circuitry configured to shift bits of the data or the calculated syndrome.

15. An apparatus, comprising:
first decoding circuitry tailored to an efficiency characteristic;
second decoding circuitry tailored to a reliability characteristic; and
preliminary circuitry configured to:
receive first data corresponding to a codeword;
calculate one or more syndromes utilizing a portion of a parity-check matrix and a portion of the first data corresponding to the portion of the parity-check matrix;
transfer the first data to the first decoding circuitry in response to at least one of the calculated one or more syndromes being determined to have a syndrome weight not exceeding a threshold syndrome weight; and
transfer the first data to the second decoding circuitry in response to at least one of the calculated one or more syndromes being determined to have a syndrome weight exceeding the threshold syndrome weight.

16. The apparatus of claim 15, wherein the parity-check matrix comprises a plurality of layers, each layer of the plurality of layers further storing one or more numerical values indicative of a quantity of bits by which the codeword or a corresponding syndrome is to shift.

17. The apparatus of claim 16, wherein the portion of the parity-check matrix corresponds to a particular layer storing one or more numerical values of zero.

18. The apparatus of claim 17, wherein the preliminary circuitry is configured to calculate the one or more syndromes utilizing:
the particular layer of the parity-check matrix that stores one or more numerical values of zero; and
a portion of a plurality of bits corresponding to the codeword.

19. The apparatus of claim 16, wherein the first decoding circuitry or the second decoding circuitry is configured to calculate one or more syndromes utilizing the plurality of layers of the parity-check matrix and the codeword.

20. The apparatus of claim 15, wherein the second decoding circuitry is capable of correcting errors on data having a higher bit error rate (BER) than the first decoding circuitry is capable of.
